(19) United States
(12) Patent Application Publication
(10) Pub. No.: US 2015/0342068 A1
(43) Pub. Date: Nov. 26, 2015

(54) DURABLE SYNCHRONOUS OPENING AND CLOSING MECHANISM

(71) Applicant: Sinher Technology Inc., New Taipei City (TW)

(72) Inventors: Ting-Hung SU, New Taipei City (TW); Yung-Chang CHIANG, New Taipei City (TW)

(73) Assignee: Sinher Technology Inc., New Taipei City (TW)

(21) Appl. No.: 14/285,048

(22) Filed: May 22, 2014

(51) Int. Cl. H05K 5/02

(52) U.S. Cl. CPC H05K 5/0226

(57) ABSTRACT

A durable synchronous opening and closing mechanism includes a support rack, a first rotation portion, a second rotation portion and a transmission member. The support rack includes a first jointing hole and a second jointing hole and at least one coupling portion. The first rotation portion includes a first rotation shaft, a plurality of integrally formed first transmission bumps extended radially outward and a first limiting portion. The second rotation portion includes a second rotation shaft, a plurality of integrally formed second transmission bumps extended radially outward and a second limiting/portion. The transmission member has an axle and a plurality of bridging bumps radially formed to engage with the first transmission bumps and second transmission bumps. The first and second limiting portions restrict rotation of the bridging bumps.

### FIELD OF THE INVENTION

The present invention relates to an opening and closing mechanism and particularly to a durable synchronous opening and closing mechanism that is integrally formed at a smaller size and also provides positioning function.

### BACKGROUND OF THE INVENTION

A conventional flip-top electronic device such as a notebook computer, mobile phone or the like generally has a hinge to bridge a display and a body to allow the display to be opened or closed against the body, and also provide a torsional force to support and anchor the display at a specific angle after being opened. In the past the hinge usually was a single pintle type with only one pintle as an axis. Although it allows the display to be flipped against the body, its opening and closing transmission efficiency is lower that significantly limits the opening and closing speed. Hence the conventional single pintle hinge can no longer meet the requirements of the market now, and dual-pintle hinges have been developed in the industry to fulfill this need.

For instance, R.O.C. patent 1255388 discloses a hinge apparatus which includes a first pintle fastened to a first frame, a first gear located on a portion of the circumference of the first pintle, a second pintle fastened to a second frame and a second gear located on a portion of the circumference of the second pintle. The first gear and second gear engage with each other to make the first pintle and second pintle to rotate in opposite directions at the same time. The gears can be spur gears or bevel gears. By providing rotation in opposite directions at the same time it increases the transmission efficiency.

While the aforesaid hinge apparatus adopts dual pintles with spur or bevel gears, the axes of the spur or bevel gears could become unparallel and result in eccentric or unparallel of the straight teeth between the gears, thus form merely point contact between the teeth that easily cause impact and friction thereof. As a result, the lifespan of the spur gears and bevel gears is shortened. Moreover, the hinge consists of spur gears and bevel gears cannot be made in a smaller size, hence is difficult to be used on smaller electronic devices. In addition, the aforesaid hinge provides merely dual-pintle transmission, but no relative positioning between the two pintles. Hence how to design a dual-pintle synchronous motion hinge with a stronger strength at a smaller size and also provide a positioning structure is an issue remained to be resolved.

### SUMMARY OF THE INVENTION

The primary object of the present invention is to solve the problems of conventional dual-pintle hinges of insufficient strength, larger size and no positioning function.

To achieve the foregoing object the present invention provides a durable synchronous opening and closing mechanism that includes a support rack, a first rotation portion, a second rotation portion and a transmission member. The support rack includes a bracket which has a first jointing hole and a second jointing hole that are separated from each other and at least one coupling portion connected to the bracket between the first jointing hole and second jointing hole. The first rotation portion includes a first rotation shaft hinged in the first jointing hole, a plurality of first transmission bumps integrally formed on the first rotation shaft and centered thereof as an axis and extended radially outward to form a first engaging arch section, and a first limiting portion which has a first limiting arch section integrally formed on the first rotation shaft and centered thereof as an axis and extended outward and joined the first engaging arch section circumferentially. The second rotation portion is parallel with the first rotation portion, and includes a second rotation shaft hinged in the second jointing hole, a plurality of second transmission bumps integrally formed on the second rotation shaft and centered thereof as an axis and extended radially outward to form a second engaging arch section, and a second limiting portion which has a second limiting arch section integrally formed on the second rotation shaft and centered thereof as an axis and extended outward and joined the second engaging arch section circumferentially. The transmission member is installed on the support rack and includes an axle hinged on the coupling portion and a plurality of bridging bumps radially formed and cantered the axle as an axis to movably engage with the first transmission bumps at the first engaging arch section and the second transmission bumps at the second engaging arch sections to make the first rotation portion and the second rotation portion to rotate against each other. The first limiting portion and second limiting portion restrict the bridging bumps to rotate within the first and second limiting arch sections.

In one embodiment the first rotation portion includes a first coupling portion connected to the first rotation shaft, and the second rotation portion includes a second coupling portion connected to the second rotation shaft.

In another embodiment the durable synchronous opening and closing mechanism includes at least one support member which is assembled with the first and second rotation portions to keep the first rotation shaft in parallel with the second rotation shaft, and includes a first pivoting hole hinged by the first rotation shaft and a second pivoting hole hinged by the second rotation shaft.

In yet another embodiment the durable synchronous opening and closing mechanism includes two torsion generating portions run through respectively by the first rotation shaft and second rotation shaft to provide torsional forces required by first rotation shaft and second rotation shaft.

In yet another embodiment the first rotation shaft includes a first latch portion and a first thread portion, and the second rotation shaft includes a second latch portion and a second thread portion. The torsion generating portion includes at least two washers latched respectively on the first latch portion and the second latch portion, and at least two elastic washers run through respectively by the first and second rotation shafts to provide torsional forces required by the first and second rotation shafts, and two fastening nuts to fasten respectively the first thread portion and the second thread portion to apply forces and generate deformation on the elastic washers.

In yet another embodiment the first transmission bumps, second transmission bumps and bridging bumps have respectively a plurality of helical protrusive traces formed in a same helical direction.

In yet another embodiment the bridging bumps are extended axially in two directions away from the surface of the axle.

Compared with the conventional structures, the durable synchronous opening and closing mechanism of the invention provides many advantageous features, notably:

1. The transmission shafts have multiple trenches extended outward radially from the surface thereof, and the transmission bumps are integrally formed on the transmission shafts and centered thereof as the axes and extended outward radially to form the engaging arch sections, and the limiting portions also are integrally formed on the transmission shafts and centered thereof as the axes and extended outward to form the limiting arch sections to join the engaging arch sections circumferentially. Moreover, the limiting portions are formed on the transmission bumps without machining, hence do not transmit drive power. As a result, the durable synchronous opening and closing mechanism has many advantages such as greater strength provided by the integrated forming, higher economic benefit because of integrated forming process and saving of fabrication processes.

2. The transmission bumps and bridging bumps are extended outward radially, hence they can engage with each other in a closer contact to increase the contact area, thereby can improve the problem of impact and friction that occurred to the conventional gear transmission.

3. Employing the transmission bumps on the rotation shafts and bridging bumps on the transmission member can make total size of the mechanism smaller than the conventional hinges that adopt spur gears for transmission. Thus the transmission distance of the invention also is shorter.

4. The first and second limiting portions are directly formed on the first and second rotation shafts, hence a relative positioning effect can be accomplished between the first and second rotation portions without the need of providing an extra positioning structure.

The foregoing, as well as additional objects, features and advantages of the invention will be more readily apparent from the following detailed description, which proceeds with reference to the accompanying drawings.

### BRIEF DESCRIPTION THE DRAWINGS

FIG. 1 is an exploded view of the durable synchronous opening and closing mechanism of the invention.

FIG. 2 is a schematic view of the durable synchronous opening and closing mechanism of the invention.

FIG. 3 is a cross section of the durable synchronous opening and closing mechanism of the invention.

FIG. 4A is a schematic view of the durable synchronous opening and closing mechanism of the invention in an operating condition.

FIG. 4B is a schematic view of the durable synchronous opening and closing mechanism of the invention in another operating condition.

FIG. 5A is a perspective view of a second embodiment of the transmission member of the invention.

FIG. 5B is a side view of the second embodiment of the transmission member of the invention.

### DETAILED DESCRIPTION OF THE PREFERRED EMBODIMENTS

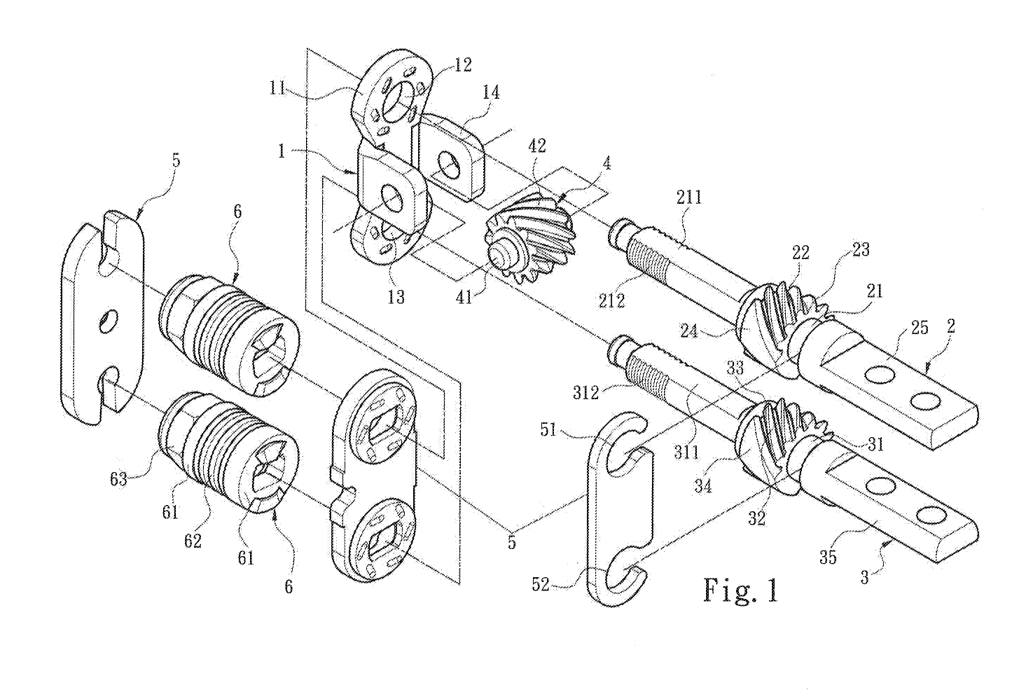

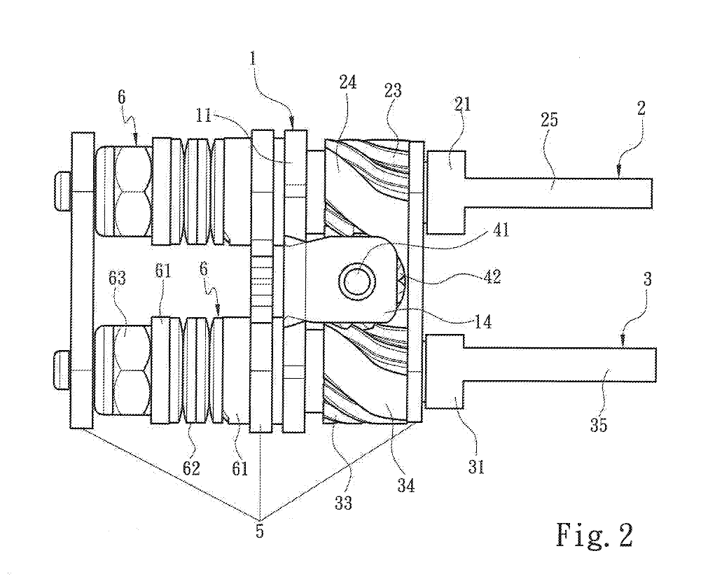

Please referring to FIGS. 1 and 2, the present invention aims to provide a durable synchronous opening and closing mechanism that includes a support rack 1, a first rotation portion 2, a second rotation portion 3 and a transmission member 4. The support rack 1 includes a bracket 11 which has a first jointing hole 12 and a second jointing hole 13 that are separated from each other, and at least one coupling portion 14 connected to the bracket 11 between the first jointing hole 12 and second jointing hole 13.

Please also referring to FIGS. 1 through 3, the first rotation portion 2 includes a first rotation shaft 21 hinged in the first jointing hole 12, a plurality of first trenches 22 formed on the first rotation shaft 21 and centered thereof as an axis and extended radially outward from the surface of the first rotation shaft 21, a plurality of first transmission bumps 23 formed integrally on the first rotation shaft 21 between the first trenches 22 and centered thereof as an axis and extended radially outward from the first rotation shaft 21, a first limiting portion 24 integrally formed on the first rotation shaft 21 and centered thereof as an axis and extended outward, and a first coupling portion 25 connected to the first rotation shaft 21. Similarly, the second rotation portion 3 is parallel with the first rotation portion 2, and includes a second rotation shaft 31 hinged in the second jointing hole 13, a plurality of second trenches 32 formed on the second rotation shaft 31 and centered thereof as an axis and extended radially outward from the surface of the second rotation shaft 31, a plurality of second transmission bumps 33 formed integrally on the second rotation shaft 31 between the second trenches 32 and extended radially outward, a second limiting portion 34 integrally formed on the second rotation shaft 31 and centered thereof as an axis and extended outward, and a second coupling portion 35 connected to the second rotation shaft 31. In this embodiment the first and second trenches 22 and 32 are formed respectively and integrally on the surfaces of the first and second rotation shafts 21 and 31 by machining or other fabrication process. In other words, by fabricating the first and second trenches 22 and 32 on the surfaces of the first and second rotation shafts 21 and 31 that are extended radially outward the first and second transmission bumps 23 and 33 also are formed at the same time with helical protrusive traces in the same direction. Furthermore, the first transmission bumps 23 form a first engaging arch section A1 on the first rotation shaft 21, and the first limiting portion 24 also has a first limiting arch section B1 formed thereon to join the first engaging arch section A1 on the circumference of the first rotation shaft 21. In addition, the transmission bumps 33 form a second engaging arch section A2 on the second rotation shaft 31, and the second limiting portion 34 also has a second limiting arch section B2 formed thereon to join the second engaging arch section A2 on the circumference of the second rotation shaft 31. While the invention forms the first and second rotation portions 2 and 3 integrally by machining, it is not the limitation of fabrication of the invention in implementation.

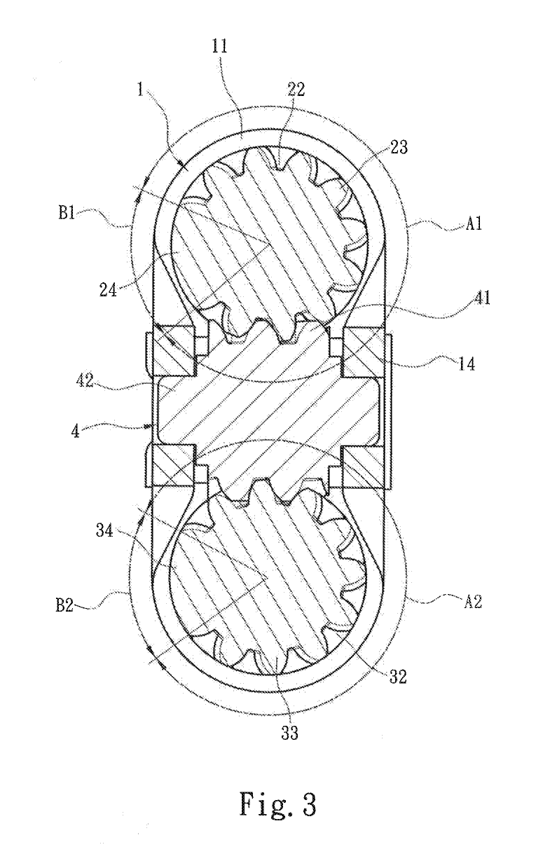

Please referring to FIGS. 1 and 3 again, the transmission member 4 is located on the support rack 1 and includes an axle 41 hinged on the coupling portion 14 and a plurality of bridging bumps 42 radially arranged on the axle 41 and centered thereof as an axis. The bridging bumps 42 are movable engaged with the first transmission bumps 23 at the first engaging arch section A1 and second transmission bumps 33 at the second engaging arch section A2 so that the first rotation portion 2 and second rotation portion 3 can rotate against each other, while the first and second limiting portions 24 and 34 restrict the bridging bumps 42 to rotate in the first and second limiting arch sections B1 and B2. Thus, when the first rotation portion 2 rotates against the support rack 1 the first transmission bumps 23 drive the bridging bumps 42 to make the transmission member 4 to rotate against the support rack 1, meanwhile the bridging bumps 42 also drive the second transmission bumps 33 to make the second rotation portion 3 to rotate against the support rack 1. On the other hand, when the second rotation portion 3 rotates against the support rack 1, the aforesaid transmission movement also takes place, details are omitted herein. In this embodiment the first and second rotation portions 2 and 3 rotate in opposite directions. In addition, in the event that the first and second trenches 22 and 32 are formed wider, the bridging bumps 42 of the transmission member 4 can be held in the first and second trenches 22 and 32 without in contact with the first and second transmission bumps 23 and 33. Hence when the first rotation portion 2 rotates against the support rack 1, it rotates first in idle without driving the transmission member 4, then the first transmission bumps 23 are in contact with the bridging bumps 42 and drive the transmission member 4 rotating, therefore such transmission is different from the conventional gear transmission. On the other hand, when the second rotation portion 3 rotates against the support rack 1, the second transmission bumps 33 also do not immediately drive the bridging bumps 42. However, there is no limitation on the width of the first and second trenches 22 and 32. The first transmission bumps 23, second transmission bumps 33 and bridging bumps 42 have respectively helical protrusive traces in the same helical direction.

Please referring to FIGS. 1 and 2 again, the durable synchronous opening and closing mechanism of the invention further includes at least one support member 5 to couple with the first and second rotation portions 2 and 3 to keep the first rotation shaft 21 in parallel with the second rotation shaft 31. The support member 5 includes a first pivoting hole 51 hinged by the first rotation shaft 21 and a second pivoting hole 52 hinged by the second rotation shaft 31. In addition, the invention also has a torsion generating portion 6 run through by the first and second rotation shafts 21 and 31 to provide torsional forces required by the first and second rotation shafts 21 and 31. For installation of the torsion generating portion 6 the first rotation shaft 21 has a first latch portion 211 and a first thread portion 212, and the second rotation shafts 31 has a second latch portion 311 and a second thread portion 312. The torsion generating portion 6 includes at least two washers 61 latched respectively on the first latch portion 211 and second latch portion 311, at least two elastic washers 62 run through respectively by the first rotation shaft 21 and second rotation shaft 31 to provide torsional forces required by the first rotation shaft 21 and second rotation shaft 31, and two fastening nuts 63 to fasten respectively the first thread portion 212 and second thread portion 312 to apply forces and produce deformation on the first and second elastic washers 62.

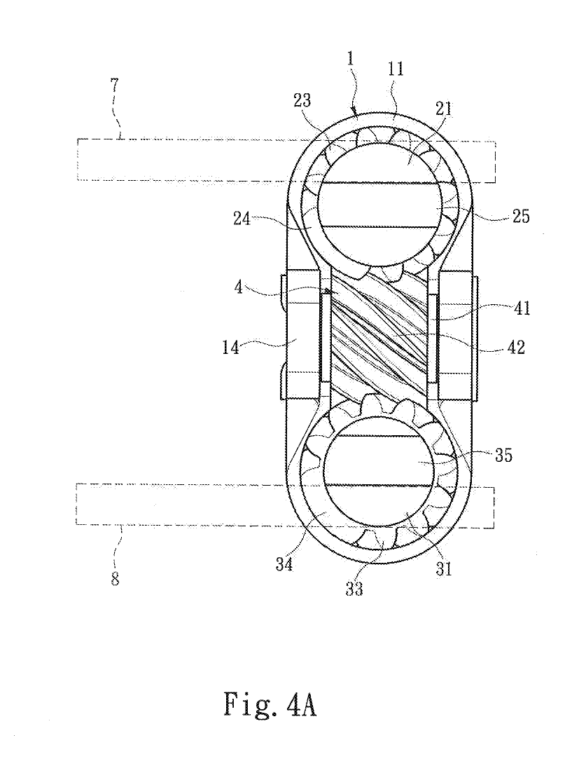

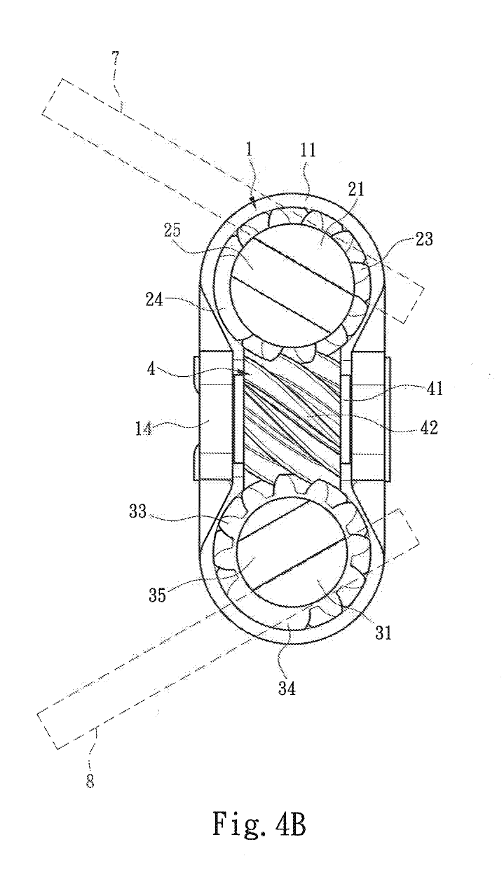

Please refer to FIGS. 4A and 4B for the durable synchronous opening and closing mechanism of the invention in operating conditions. It is to be noted that the first rotation portion 2 can be driven to drive the second rotation portion 3, or vice versa, or the first and second rotation portions 2 and 3 can be driven at the same time and generate mutual transmission. The following discussion merely focuses on the first rotation portion 2 rotating to drive the transmission member 4 which in turn drives the second rotation portion 3, but this is not the limitation of the invention. When the first rotation shaft 21 rotates, the first transmission bumps 23 drive the bridging bumps 42 of the transmission member 4, that in turn drive the second transmission bumps 33 of the second rotation shaft 31. Hence the first rotation portion 2, transmission member 4 and second rotation portion 3 form a mutual chained movement and rotate together. In addition, when the first rotation portion 2 rotates to a specific position with the bridging bumps 42 in contact with the first limiting portion 24, the bridging bumps 42 are restricted by the first limiting portion 24 so that the transmission member 4 cannot rotate continuously. Moreover, through design, the bridging bumps 42 can also be restricted by the first and second limiting portions 24 and 34 at the same time to stop the transmission member 4 from transmitting continuously.

Also referring to FIGS. 4A and 4B, the first coupling portion 25 of the first rotation portion 2 can be fastened to a first base 7, and the second coupling portion 35 of the second rotation portion 3 can be fastened to a second base 8. When the first base 7 or second base 8 is turned, the second base 8 or first base 7 also is turned because of the durable synchronous opening and closing mechanism. In addition, if the first base 7 and second base 8 are turned at the same time for a specific angle, the durable synchronous opening and closing mechanism provides feedback by doubling the specific angle for opening or closing. Hence users can open or close the first base 7 and second base 8 faster. Furthermore, when the first base 7 or second base 8 is turned to the aforesaid specific position with the bridging bumps 42 in contact with the first limiting portion 24 or the second limiting portion 34, or the first limiting portion 24 and second limiting portion 34 at the same time, the first base 7 and second base 8 also generate mutual positioning effect for anchoring.

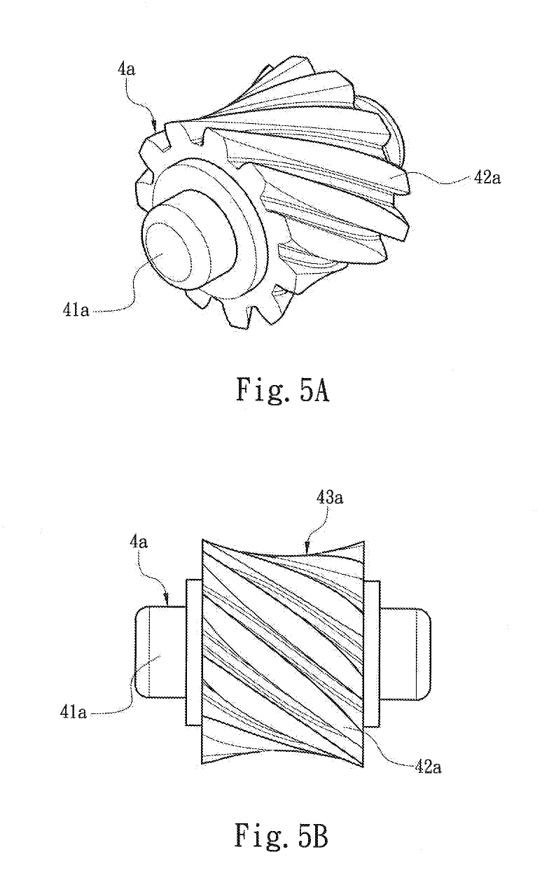

Aside from the first embodiment previously discussed, please referring to FIGS. 5A and 5B for a second embodiment of the transmission member 4a of the invention, in which the transmission member 4a includes an axle 41a and a plurality of bridging bumps 42a formed radially on the axle 41a and centered thereof as an axis and extended away in both directions from the surface of the axle 41a. Namely, viewed the transmission member 4a radially, the bridging bumps 42a is concaved in the middle to form an annular recess 43a with two sides protrusive gradually. Hence when the transmission member 4a is engaged with the first and second rotation portions 2 and 3, the recess 43a can shorten the interval of the first and second rotation shafts 21 and 31. This embodiment also can increase the contact area between the bridging bumps 42a and the first and second transmission bumps 23 and 33, thereby makes transmission between the first and second rotation portions 2 and 3 steadier. In addition, the bridging bumps 42a, first and second transmission bumps 23 and 33 have respectively helical protrusive traces formed in the same helical direction.

As a conclusion, the durable synchronous opening and closing mechanism of the invention mainly includes a support rack, a first rotation portion, a second rotation portion and a transmission member. The first rotation portion and second rotation portion are installed on the support rack. The first rotation portion includes a first rotation shaft, a plurality of first transmission bumps integrally formed on the first rotation shaft and centered thereof as an axis and extended radially outward to form a first engaging arch section, and a first limiting portion which has a first limiting arch section integrally formed on the first rotation shaft and centered thereof as an axis and extended outward and joined the first engaging arch section circumferentially. The second rotation portion includes a second rotation shaft, a plurality of second transmission bumps integrally formed on the second rotation shaft and centered thereof as an axis and extended radially outward to form a second engaging arch section, and a second limiting portion which has a second limiting arch section integrally formed on the second rotation shaft and centered thereof as an axis and extended outward and joined the second engaging arch section circumferentially. The transmission member also is hinged on the support rack and includes an axle and a plurality of bridging bumps radially formed on the axle and centered thereof as an axis to engage with the first transmission bumps at the first engaging arch sections and also engage with the second transmission bumps at the second engaging arch sections to make the first rotation portion to rotate against the second rotation portion. The first limiting portion and second limiting portion restrict the bridging bumps to rotate within the first and second limiting arch sections. Hence the transmission member can drive movement of the first rotation portion or second rotation portion, thereby rotate the first rotation portion and second rotation portion at a higher efficiency. In addition, the durable synchronous opening and closing mechanism thus formed has a greater strength, smaller size and provides mutual positioning for two shafts.

What is claimed is:

1. A durable synchronous opening and closing mechanism, comprising:
a support rack including a bracket which contains a first jointing hole and a second jointing hole, and at least one coupling portion connected to the bracket between the first jointing hole and the second jointing hole;
a first rotation portion and a second rotation portion parallel with the first rotation portion, the first rotation portion including a first rotation shaft hinged in the first jointing hole, a plurality of first transmission bumps integrally formed on the first rotation shaft and extended radially outward to form a first engaging arch section, and a first limiting portion which is integrally formed on the first rotation shaft and extended radially outward to form a first limiting arch section to join the first engaging arch section circumferentially; the second rotation portion including a second rotation shaft hinged in the second jointing hole, a plurality of second transmission bumps integrally formed on the second rotation shaft and extended radially outward to form a second engaging arch section, and a second limiting portion which is integrally formed on the second rotation shaft and extended radially outward to form a second limiting arch section to join the second engaging arch section circumferentially; and
a transmission member which is installed on the support rack and includes an axle hinged on the coupling portion and a plurality of bridging bumps radially formed on the axle to engage with the first transmission bumps at the first engaging arch section and also engage with the second transmission bumps at the second engaging arch section to make the first rotation portion and the second rotation portion to rotate against each other, the first limiting portion and the second limiting portion limiting the bridging bumps to rotate within the first and the second limiting arch sections.

2. The durable synchronous opening and closing mechanism of claim 1, wherein the first rotation portion includes a first coupling portion connected to the first rotation shaft, and the second rotation portion includes a second coupling portion connected to the second rotation shaft.

3. The durable synchronous opening and closing mechanism of claim 1 further including at least one support member to couple with the first rotation portion and the second rotation portion to keep the first rotation shaft parallel with the second rotation shaft, the support member containing a first pivoting hole hinged by the first rotation shaft and a second pivoting hole hinged by the second rotation shaft.

4. The durable synchronous opening and closing mechanism of claim 3 further including two torsion generating portions run through respectively by the first rotation shaft and the second rotation shaft to provide torsional forces required by the first rotation shaft and the second rotation shaft.

5. The durable synchronous opening and closing mechanism of claim 4, wherein the first rotation shaft includes a first latch portion and a first thread portion, and the second rotation shaft includes a second latch portion and a second thread portion, the torsion generating portions including at least two washers latched respectively on the first latch portion and the second latch portion, at least two elastic washers run through respectively by the first rotation shaft and the second rotation shaft to provide the torsional forces required by the first rotation shaft and the second rotation shaft, and two fastening nuts fastened respectively to the first thread portion and the second thread portion to apply forces and generate deformation on the elastic washers.

6. The durable synchronous opening and closing mechanism of claim 5, wherein the first transmission bumps, the second transmission bumps and the bridging bumps contain respectively a plurality of helical protrusive traces in a same helical direction.

7. The durable synchronous opening and closing mechanism of claim 1, wherein the first transmission bumps, the second transmission bumps and the bridging bumps contain respectively a plurality of helical protrusive traces in a same helical direction.

8. The durable synchronous opening and closing mechanism of claim 1, wherein the bridging bumps are extended axially in two directions away from the surface of the axle.

9. The durable synchronous opening and closing mechanism of claim 8, wherein the first transmission bumps, the second transmission bumps and the bridging bumps contain respectively a plurality of helical protrusive traces in a same helical direction.
